(19) United States
(12) Patent Application Publication
(10) Pub. No.: US 2025/0067556 A1
(43) Pub. Date: Feb. 27, 2025

(54) METHOD OF MEASURING FILM THICKNESS, AND SUBSTRATE PROCESSING APPARATUS

(71) Applicant: Tokyo Electron Limited, Tokyo (JP)

(72) Inventors: Yuji OTSUKI, Albany, NY (US); Munehito KAGAYA, Tokyo (JP); Yusuke SUZUKI, Nirasaki-shi (JP)

(21) Appl. No.: 18/944,260

(22) Filed: Nov. 12, 2024

Related U.S. Application Data
(63) Continuation of application No. PCT/JP2023/017163, filed on May 2, 2023.

(30) Foreign Application Priority Data
May 17, 2022 (JP) 2022-080876

(51) Int. Cl. G01B 11/06; H01L 21/66

(52) U.S. Cl. CPC G01B 11/0625; H01L 22/26; G01B 2210/56

(57) ABSTRACT

A method of measuring a film thickness includes: storing, in a storage, relationship information indicating a relationship between an absorbance spectrum of a substrate, which has a recess formed therein and is subjected to substrate processing, and a film thickness of a film in the substrate subjected to the substrate processing, the absorbance spectrum being within a range including a peak of at least one of LO (Longitudinal Optical) phonons or TO (Transverse Optical) phonons of the film present on a surface of the substrate; performing the substrate processing on the substrate having the recess formed therein; measuring the absorbance spectrum of the substrate subjected to the substrate processing; and deriving, based on the relationship information, the film thickness of the film present on the surface of the substrate subjected to the substrate processing, from the measured absorbance spectrum.

### CROSS-REFERENCE TO RELATED APPLICATIONS

This application is a bypass continuation application of international application No. PCT/JP2023/017163 having an international filing date of May 2, 2023 and designating the United States, the international application being based upon and claiming the benefit of priority from Japanese Patent Application No. 2022-080876, filed on May 17, 2022, the entire contents of which are incorporated herein by references.

### TECHNICAL FIELD

The present disclosure relates to a method of measuring a film thickness and a substrate processing apparatus.

### BACKGROUND

Patent Document 1 discloses a technique for filling a recess formed in a SiO₂ film on the surface of a wafer with no gap when forming a SiN film to fill the recess.

### PRIOR ART DOCUMENT

### Patent Document

Patent Document 1: Japanese Laid-Open Patent Publication No. 2017-174902

### SUMMARY

A method of measuring a film thickness includes: storing, in a storage, relationship information indicating a relationship between an absorbance spectrum of a substrate, which has a recess formed therein and is subjected to substrate processing, and a film thickness of a film in the substrate subjected to the substrate processing, the absorbance spectrum being within a range including a peak of at least one of LO (Longitudinal Optical) phonons or TO (Transverse Optical) phonons of a film present on a surface of the substrate; performing the substrate processing on the substrate having the recess formed therein; measuring the absorbance spectrum of the substrate subjected to the substrate processing; and deriving, based on the relationship information, the film thickness of the film present on the surface of the substrate subjected to the substrate processing, from the measured absorbance spectrum.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view showing an example of a film forming apparatus according to an embodiment.

FIG. 2 is a view showing a state in which a substrate is raised from a stage in the film forming apparatus according to the embodiment.

FIG. 3 is a schematic configuration view showing another example of the film forming apparatus according to the embodiment.

FIG. 4 is a view showing an example of a substrate on which a film according to an embodiment is formed.

FIG. 5 is a view for explaining a FT-IR analysis in the related art.

FIG. 6A is a view for explaining an influence of phonons on a flat substrate.

FIG. 6B is a view for explaining an influence of phonons on a flat substrate.

FIG. 7A is a view for explaining an influence of phonons on a substrate on which a recess is formed.

FIG. 7B is a view showing an example of an absorbance spectrum on the substrate on which the recess is formed.

FIG. 8A is a view showing an example of an absorbance spectrum according to an embodiment.

FIG. 8B is a view showing an example of an absorbance spectrum according to an embodiment.

FIG. 9A is a view showing an example of an absorbance spectrum according to an embodiment.

FIG. 9B is a view showing an example of a relationship between an area of the absorbance spectrum and a film thickness according to an embodiment.

FIG. 10A is a view for explaining an example of a flow for deriving the film thickness according to an embodiment.

FIG. 10B is a view for explaining an example of a flow for deriving the film thickness according to an embodiment.

FIG. 11A is a view showing an example of the substrate on which the film according to an embodiment is formed.

FIG. 11B is a view showing an example of the absorbance spectrum according to an embodiment.

FIG. 11C is a view showing an example of a relationship between an area of the absorbance spectrum and a film thickness according to an embodiment.

FIG. 12A is a view showing an example of the substrate on which the film according to an embodiment is formed.

FIG. 12B is a view showing an example of the absorbance spectrum according to an embodiment.

FIG. 12C is a view showing an example of a relationship between an area of the absorbance spectrum and a film thickness according to an embodiment.

FIG. 13A is a view showing an example of the absorbance spectrum according to an embodiment.

FIG. 13B is a view showing an example of a relationship between an area of the absorbance spectrum and a film thickness according to an embodiment.

FIG. 14A is a view showing an example of a relationship between a feature amount of the absorbance spectrum and the film thickness according to an embodiment.

FIG. 14B is a view showing an example of the relationship between the feature amount of the absorbance spectrum and the film thickness according to an embodiment.

FIG. 15A is a view showing an example of an absorbance spectrum according to an embodiment.

FIG. 15B is a view showing an example of a relationship between an area of the absorbance spectrum and a film thickness according to an embodiment.

FIG. 16A is a view showing an example of an absorbance spectrum according to an embodiment.

FIG. 16B is a view showing an example of a relationship between a peak wave number of the absorbance spectrum and a film thickness according to an embodiment.

FIG. 16C is a view showing an example of a relationship between a center-of-gravity wave number of the absorbance spectrum and the film thickness according to an embodiment.

FIG. 17A is a view showing an example of an absorbance spectrum according to an embodiment.

FIG. 17B is a view showing an example of the absorbance spectrum according to an embodiment.

FIG. 18A is a view showing an example of an absorbance spectrum according to an embodiment.

FIG. 18B is a view for explaining an example of a flow for deriving a change in film thickness according to an embodiment.

FIG. 19 is a flowchart showing an example of a flow of a film thickness measurement method according to an embodiment.

FIG. 20 is a schematic configuration view showing another example of a film forming apparatus according to an embodiment.

FIG. 21A is a view showing an example of a schematic configuration of a measurer according to an embodiment.

FIG. 21B is a view showing an example of the schematic configuration of the measurer according to an embodiment.

### DETAILED DESCRIPTION

Hereinafter, embodiments of a method of measuring a film thickness and a substrate processing apparatus disclosed in the present disclosure will be described in detail with reference to the drawings. The method and the substrate processing apparatus described herein are not limited to the present embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the manufacture of semiconductor devices, a substrate such as a semiconductor wafer on which a pattern including recesses is formed is subjected to substrate processing such as a film-forming process of forming a film, and an etching process of etching the film on a surface of the substrate. In the manufacture of semiconductor devices, with the progress of miniaturization of the semiconductor devices, it is necessary to accurately detect a film thickness of the film on the substrate subjected to the substrate processing.

Therefore, a technique for detecting a film thickness of a film present on a surface of a substrate in which a recess is formed is needed.

### EMBODIMENTS

### [Configuration of Film Forming Apparatus]

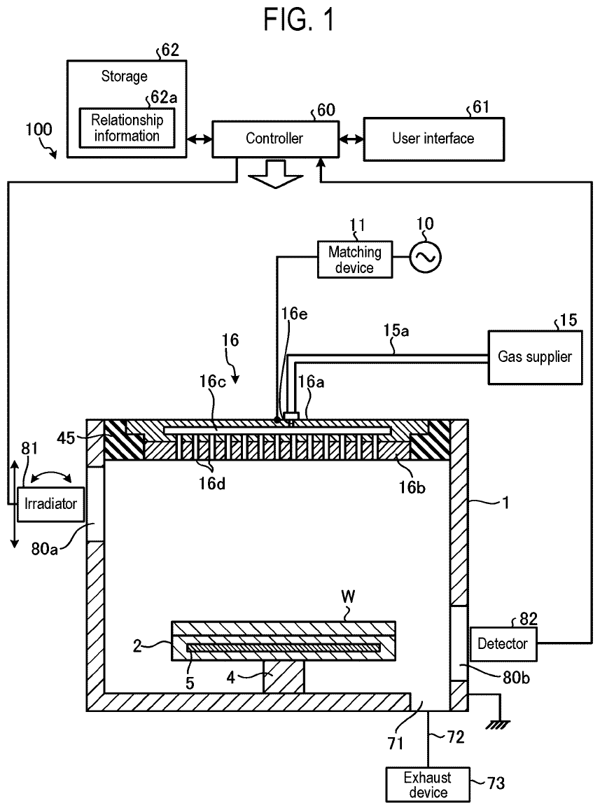

Next, embodiments will be described. First, an example of a substrate processing apparatus disclosed herein will be described. In the following, a case in which the substrate processing apparatus disclosed in the present disclosure is a film forming apparatus 100 and a film is formed by being subjected to substrate processing by the film forming apparatus 100 will be mainly described as an example. FIG. 1 is a schematic cross-sectional view showing an example of a schematic configuration of the film forming apparatus 100 according to an embodiment. In this embodiment, the film forming apparatus 100 corresponds to the substrate processing apparatus of the present disclosure. In one embodiment, the film forming apparatus 100 is an apparatus which forms a film on a substrate W. The film forming apparatus 100 shown in FIG. 1 includes an airtight chamber 1 which is electrically connected to a ground potential. The chamber 1 has a cylindrical shape and is made of, for example, aluminum, nickel, or the like whose surface is anodized. A stage 2 is provided inside the chamber 1.

The stage 2 is made of metal such as aluminum or nickel. The substrate W such as a semiconductor wafer is placed on an upper surface of the stage 2. The stage 2 supports the substrate W placed horizontally. A lower surface of the stage 2 is electrically connected to a support member 4 made of a conductive material. The stage 2 is supported by the support member 4. The support member 4 is supported by a bottom surface of the chamber 1. A lower end of the support member 4 is electrically connected to the bottom surface of the chamber 1 and is grounded via the chamber 1. The lower end of the support member 4 may be electrically connected to the bottom surface of the chamber 1 via a circuit configured to reduce an impedance between the stage 2 and the ground potential.

The stage 2 includes a built-in heater 5. The substrate W placed on the stage 2 may be heated to a predetermined temperature by the heater 5. The stage 2 may include a flow path (not shown) formed therein through which refrigerant circulates. The refrigerant whose temperature is controlled by a chiller unit provided outside the chamber 1 may be supplied into the flow path to circulate therein. The stage 2 may control the substrate W to have the predetermined temperature by the heating by the heater 5 and a cooling action by the refrigerant supplied from the chiller unit. The stage 2 does not have to include the heater 5 and may control the temperature of the substrate W only with the refrigerant supplied from the chiller unit.

The stage 2 may include an electrode embedded therein. The stage 2 may adsorb the substrate W placed on the upper surface of the stage 2 by virtue of an electrostatic force generated by a DC voltage supplied to the electrode.

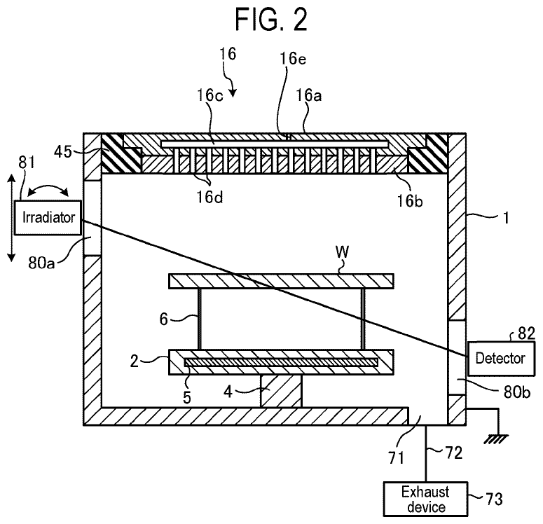

The stage 2 is provided with lifting pins 6 for raising and lowering the substrate W. In the film forming apparatus 100, when the substrate W is transferred or when infrared spectroscopy analysis is performed on the substrate W, the lifting pins 6 are protruded from the stage 2 to support the substrate W from below so that the substrate W is raised from the stage 2. FIG. 2 is a view showing a state in which the substrate W is raised from the stage 2 in the film forming apparatus 100 according to the embodiment. The substrate W is transferred to the film forming apparatus 100. For example, a loading/unloading port (not shown) for loading/unloading the substrate W is provided in a sidewall of the chamber 1. A gate valve for opening/closing the loading/unloading port is provided at the loading/unloading port. When the substrate W is loaded/unloaded, the gate valve remains opened. The substrate W is loaded into the chamber 1 via the loading/unloading port by a transfer mechanism (not shown) provided inside a transfer chamber. The film forming apparatus 100 receives the substrate W from the transfer mechanism by controlling an elevating mechanism (not shown) provided outside the chamber 1 to raise the lifting pins 6. After the transfer mechanism is withdrawn, the film forming apparatus 100 controls the elevating mechanism to lower the lifting pins 6 so as to place the substrate W on the stage 2.

A shower head 16 formed in a substantially disc shape is provided above the stage 2 and on an inner side of the chamber 1. The shower head 16 is supported in an upper portion of the stage 2 via an insulating member 45 such as ceramics. As a result, the chamber 1 is electrically insulated from the shower head 16. The shower head 16 is formed of conductive metal such as nickel.

The shower head 16 includes a top plate member 16a and a shower plate 16b. The top plate member 16a is provided so as to cover an interior of the chamber 1 from above. The shower plate 16b is provided below the top plate member 16a so as to face the stage 2. A gas diffusion space 16c is formed in the top plate member 16a. A large number of gas discharge holes 16d are formed in the top plate member 16a and the shower plate 16b in a distributed manner to open toward the gas diffusion space 16c.

A gas introduction port 16e for introducing various gases into the gas diffusion space 16c is formed in the top plate member 16a. A gas supply path 15a is connected to the gas introduction port 16e. A gas supplier 15 is connected to the gas supply path 15a.

The gas supplier 15 includes gas supply lines connected to gas sources of various gases used for film formation, respectively. Each gas supply line branches appropriately according to a film-forming process and is provided with control devices for controlling a flow rate of a gas, for example, a valve such as an opening/closing valve, and a flow rate controller such as a mass flow controller. The gas supplier 15 may control the flow rates of various gases by controlling the control devices such as the opening/closing valve and the flow rate controller provided in each gas supply line.

The gas supplier 15 supplies various gases used for the film formation to the gas supply path 15a. For example, the gas supplier 15 supplies a raw material gas for film formation to the gas supply path 15a. The gas supplier 15 also supplies a purge gas or a reaction gas, which reacts with the raw material gas, to the gas supply path 15a. The gas supplied to the gas supply path 15a is diffused in the gas diffusion space 16c and discharged from each gas discharge hole 16d.

A space surrounded by a lower surface of the shower plate 16b and the upper surface of the stage 2 forms a processing space where the film-forming process is performed. In addition, the shower plate 16b is paired with the stage 2 and is configured as an electrode plate for forming a capacitively-coupled plasma (CCP) in the processing space. A radio-frequency power supply 10 is connected to the shower head 16 via a matching device 11. Radio-frequency power (RF power) is applied from the radio-frequency power supply 10 to a gas supplied to the processing space 40 via the shower head 16, thereby forming plasma in the processing space. The radio-frequency power supply 10 may be connected to the stage 2 instead of the shower head 16. The shower head 16 may be grounded. In this embodiment, constituent elements which perform the film formation, such as the shower head 16, the gas supplier 15, and the radio-frequency power supply 10, correspond to a substrate processor of the present disclosure. In this embodiment, the substrate processor performs a film-forming process on the substrate W, as the substrate processing.

An exhaust port 71 is formed at the bottom of the chamber 1. An exhaust device 73 is connected to the exhaust port 71 via an exhaust pipe 72. The exhaust device 73 includes a vacuum pump and a pressure regulating valve. The exhaust device 73 may reduce and regulate an internal pressure of the chamber 1 to a predetermined level of vacuum by operating the vacuum pump and the pressure regulating valve.

The film forming apparatus 100 according to this embodiment may perform infrared spectroscopy (IR) analysis on the substrate W inside the chamber 1 to detect a state of the film formed on the substrate W. The infrared spectroscopy includes a method of irradiating the substrate W with infrared light and measuring light (transmitted light) transmitted through the substrate W (transmission method), and a method of measuring light (reflected light) reflected from the substrate W (reflection method). The film forming apparatus 100 shown in FIG. 1 shows an example of a configuration in which the transmitted light transmitted through the substrate W is measured. The chamber 1 includes windows 80a and 80b provided on sidewalls facing each other across the stage 2. The window 80a is provided at a relatively high position on the sidewall. The window 80b is provided at a relatively low position on the sidewall. A member such as quartz, which is transparent to the infrared light, is fitted into each of the windows 80a and 80b so that they are hermetically sealed. An irradiator 81 configured to irradiate infrared light is provided outside the window 80a. A detector 82 configured to detect infrared light is provided outside the window 80b.

When the infrared spectroscopy analysis is performed using the transmission method, as shown in FIG. 2, the film forming apparatus 100 protrudes the lifting pins 6 from the stage 2 and raises the substrate W from the stage 2. Positions of the window 80a and the irradiator 81 are adjusted so that the infrared light irradiated from the irradiator 81 is irradiated onto the upper surface of the raised substrate W via the window 80a. In addition, positions of the window 80b and the detector 82 are adjusted so that the transmitted light of the infrared light that has transmitted through the raised substrate W enters the detector 82 via the window 80b.

The irradiator 81 is arranged so that the irradiated infrared light hits a predetermined area near the center of the raised substrate W via the window 80a. The detector 82 is arranged so that the transmitted light that has transmitted through the predetermined area of the substrate W enters via the window 80b.

The film forming apparatus 100 according to this embodiment detects a state of the film formed on the substrate W by obtaining absorbance of the transmitted light transmitted through the substrate W for each wave number using the infrared spectroscopy. Specifically, the film forming apparatus 100 detects a film thickness of the film formed on the substrate W by obtaining the absorbance of the transmitted light transmitted through the substrate W for each wave number using a Fourier transform infrared spectroscopy.

The irradiator 81 may incorporate a light source configured to emit the infrared light, and optical elements such as mirrors and lenses, and may irradiate interfered infrared light. For example, the irradiator 81 splits an intermediate portion of an optical path of the infrared light generated by the light source until it is emitted to the outside into two optical paths using a half mirror or the like. An optical path length of one optical path may be varied relative to an optical path length of the other optical path to change an optical path difference therebetween for interference. As a result, infrared light of various interference waves with different optical path differences is irradiated. The irradiator 81 may be provided with a plurality of light sources. The infrared light of each light source may be controlled by an optical element to irradiate the infrared light of various interference waves with different optical path differences.

The detector 82 detects a signal intensity of the transmitted light due to the infrared light of various interference waves transmitted through the substrate W. In this embodiment, constituent elements which perform infrared spectroscopy measurement, such as the irradiator 81 and the detector 82, correspond to a measurer of the present disclosure.

An operation of the film forming apparatus 100 configured as described above is comprehensively controlled by the controller 60. The controller 60 is connected to a user interface 61 and a storage 62.

The user interface 61 includes an operator such as a keyboard through which a process manager inputs commands to manage the film forming apparatus 100, and a display which visually displays operating status of the film forming apparatus 100. The user interface 61 receives various operations. For example, the user interface 61 receives a predetermined operation to instruct the start of plasma processing.

The storage 62 stores programs (software) for implementing various processes executed by the film forming apparatus 100 under the control of the controller 60, as well as data such as process conditions and process parameters. For example, the storage 62 stores relationship information 62a. The programs and data may be used in a state of being stored in a non-transitory computer-readable recording medium (e.g., a hard disk, a CD, a flexible disk, a semiconductor memory, etc.). Alternatively, the programs and data may also be used online by transmitting them from other devices at any time via, for example, a dedicated line.

The relationship information 62a is data showing a relationship between the absorbance spectrum and the film thickness of the film formed on the substrate W. Details of the relationship information 62a will be described later.

The controller 60 is, for example, a computer including a processor, a memory, and the like. The controller 60 reads out the programs and data from the storage 62 based on instructions from the user interface 61, or the like, and controls each part of the film forming apparatus 100 to execute operations of a method of measuring the film thickness, which will be described later.

The controller 60 is connected to the irradiator 81 and the detector 82 via an interface (not shown) for performing the input and output of data, and inputs and outputs various pieces of information. The controller 60 controls the irradiator 81 and the detector 82. For example, the irradiator 81 irradiates various interference waves with different optical path differences based on control information from the controller 60. The controller 60 also receives information about a signal intensity of the infrared light detected by the detector 82.

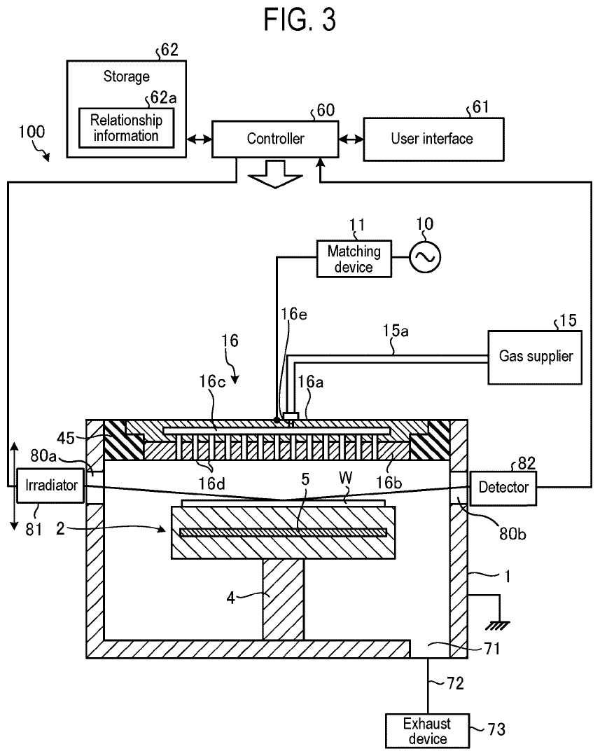

Hereinafter, an example in which the film forming apparatus 100 is configured to measure the transmitted light transmitted through the substrate W, so that the infrared spectroscopy analysis by the transmission method may be performed, will be described with reference to FIGS. 1 and 2. However, the film forming apparatus 100 may be configured to perform the infrared spectroscopy analysis by the reflection method. FIG. 3 is a schematic configuration view showing another example of the film forming apparatus 100 according to the embodiment. The film forming apparatus 100 shown in FIG. 3 shows an example in which the film forming apparatus 100 is configured to measure the reflected light that has been reflected from the substrate W.

In the film forming apparatus 100 shown in FIG. 3, windows 80a and 80b are provided at positions on the sidewall of the chamber 1, which face each other across the stage 2. An irradiator 81 which irradiates infrared light is provided outside the window 80a. A detector 82 which may detect the infrared light is provided outside the window 80b. The positions of the window 80a and the irradiator 81 are adjusted so that the infrared light irradiated from the irradiator 81 is irradiated onto the substrate W via the window 80a. In addition, the positions of the window 80b and the detector 82 are adjusted so that the infrared light reflected by the substrate W is incident on the detector 82 via the window 80b. In addition, a loading/unloading port (not shown) for loading/unloading the substrate W therethrough is provided in the sidewall of the chamber 1 at a position different from the windows 80a and 80b. A gate valve for opening/closing the loading/unloading port is provided at the loading/unloading port.

The irradiator 81 is arranged so that the irradiated infrared light hits a predetermined area near the center of the substrate W via the window 80a. The detector 82 is arranged so that the infrared light reflected from the predetermined area of the substrate W enters via the window 80b. In this way, the film forming apparatus 100 shown in FIG. 3 is capable of performing the infrared spectroscopy analysis by the reflection method.

The film forming apparatus 100 according to the embodiment may be configured so that an incident angle and irradiation position of the light incident on the substrate W from the irradiator 81 may be changed. For example, in FIGS. 1 and 3, the irradiator 81 is configured to be movable in a vertical direction and rotatable by a driving mechanism (not shown), so that the incident angle and irradiation position of the light incident on the substrate W from the irradiator 81 may be changed.

Next, a flow of performing a film-forming process as substrate processing on the substrate W by the film forming apparatus 100 according to the embodiment will be briefly described. The substrate W is placed on the stage 2 by a transfer mechanism such as a transfer arm (not shown). The substrate W has a pattern including recesses formed therein. When performing the film-forming process on the substrate W, the film forming apparatus 100 reduces the internal pressure of the chamber 1 by the exhaust device 73. The film forming apparatus 100 supplies various gases used for film formation from the gas supplier 15 and introduces a processing gas into the chamber 1 from the shower head 16. Then, the film forming apparatus 100 supplies radio-frequency power from the radio-frequency power supply 10 to generate plasma in the processing space and performs the film formation on the substrate W.

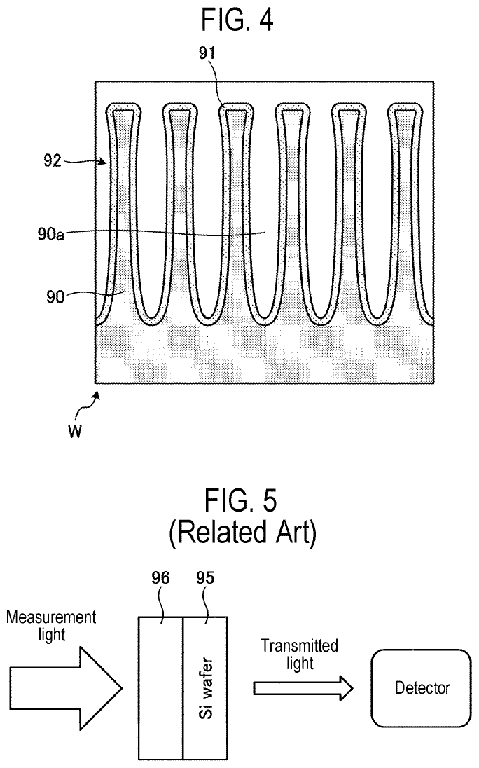

FIG. 4 is a view showing an example of the substrate W on which a film according to the embodiment is formed. The substrate W has a pattern 90 including nanoscale recesses 90a formed therein. For example, in FIG. 4, the substrate W has a trench 92 formed therein as the pattern 90 including a plurality of recesses 90a. FIG. 4 is a schematic view showing a state in which a film 91 is formed on the pattern 90 having the recesses 90a by plasma ALD. For example, in FIG. 4, the film 91 is formed on the trench 92 formed on the substrate W.

In the manufacture of semiconductor devices, a substrate such as a semiconductor wafer on which a pattern including recesses is formed is subjected to substrate processing such as a film-forming process for forming a film and an etching process for etching the film on the surface of the substrate. In the manufacture of semiconductor devices, with the progress of miniaturization of semiconductor devices, it is necessary to accurately detect a film thickness of a film on a substrate subjected to the substrate processing.

As a technique for analyzing a formed film, for example, there is infrared spectroscopy such as Fourier transform infrared spectroscopy (FT-IR).

FIG. 5 is a view for explaining a FT-IR analysis in the related art. In the FT-IR analysis in the related art, a film is formed on a flat monitor substrate provided separately from the actual substrate W on which a semiconductor device is manufactured, infrared light is irradiated onto the monitor substrate, and light transmitted through the monitor substrate is analyzed to infer a film thickness of the film formed on the actual substrate W. FIG. 5 shows a schematic view of a state where a film 96 is formed by plasma ALD on a flat silicon substrate 95 for monitor use under the same film forming conditions as the film 91. In FIG. 5, infrared light is irradiated onto the silicon substrate 95, and light transmitted through the silicon substrate 95 is detected by a detector for FT-IR analysis. In the FT-IR analysis, an absorbance spectrum that indicates the absorbance of infrared light for each wave number of the transmitted light is obtained.

However, a shape of the absorbance spectrum differs between the actual substrate W for manufacturing semiconductor devices and the silicon substrate 95 for monitor use. Even if the film 96 formed on the silicon substrate 95 is subjected to the FT-IR analysis, the film thickness of the film 91 formed on the substrate W may not be obtained with high accuracy.

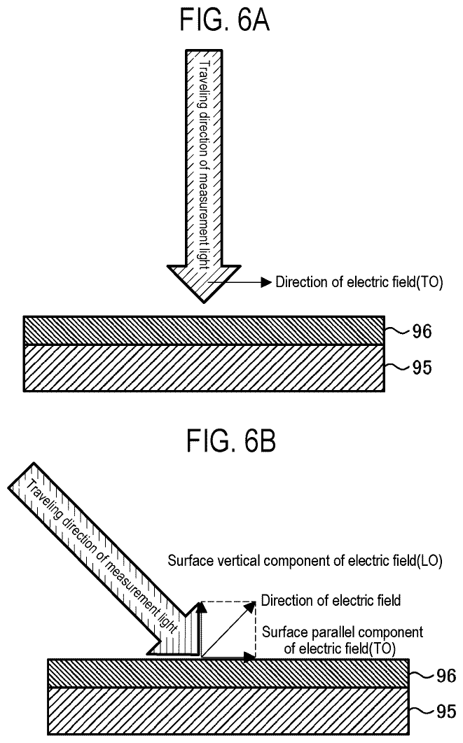

Here, an effect of phonons in the FT-IR analysis will be described. FIGS. 6A and 6B are views for explaining the effect of phonons on a flat substrate. FIGS. 6A and 6B show a case in which infrared light is incident as measurement light on the flat silicon substrate 95. The film 96 is formed on a surface of the silicon substrate 95. In the FT-IR analysis, the infrared light transmitted through or reflected by the silicon substrate 95 is detected to obtain an absorbance spectrum. FIG. 6A shows a case in which the measurement light is incident vertically on the flat silicon substrate 95. When the measurement light is incident vertically as in FIG. 6A, an electric field of the measurement light is only parallel to the surface of the silicon substrate 95. In this case, TO (Transverse Optical) phonons, which are surface parallel components of the film 96 on the surface of the silicon substrate 95, are observed. FIG. 6B shows a case in which the infrared light is obliquely incident as the measurement light on the flat silicon substrate 95. When the measurement light is obliquely incident as in FIG. 6B, the electric field of the measurement light is oblique to the silicon substrate 95. In this case, TO phonons, which are surface parallel components of the film 96 on the surface of the silicon substrate 95, are observed due to the surface parallel components of the electric field of the measurement light with respect to the silicon substrate 95. In addition, LO (Longitudinal Optical) phonons, which are perpendicular parallel components of the film 96 on the surface of the silicon substrate 95, are observed due to the surface perpendicular components of the electric field of the measurement light with respect to the silicon substrate 95.

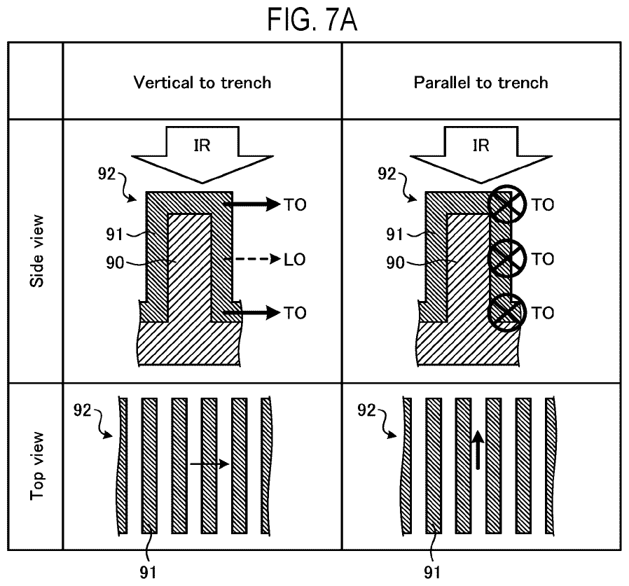

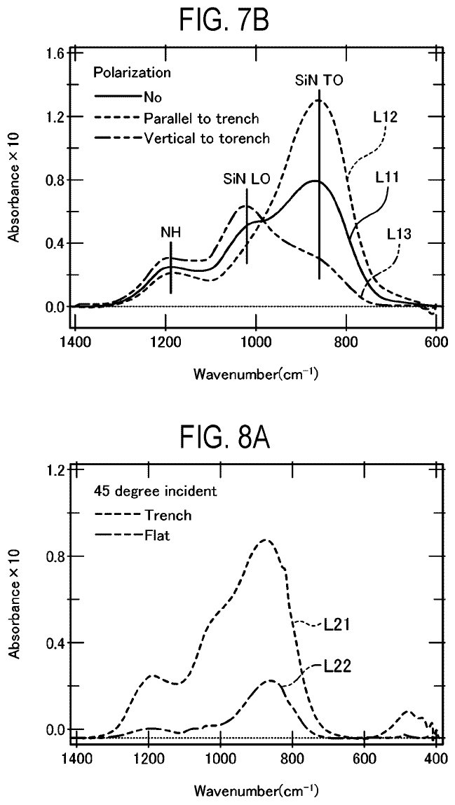

FIG. 7A is a view for explaining the effect of phonons on the substrate W in which recesses 90a are formed. In the substrate W, a trench 92 is formed as a pattern 90 including a plurality of recesses 90a, and a film 91 is formed on the trench 92. In FIG. 7A, a cross section of the trench 92 is shown as a “Side view” and the top surface of the trench 92 is shown as a “Top view.” As shown in the “Top view,” a plurality of trenches 92 are formed in a line in the vertical direction. FIG. 7A shows a case in which the infrared light is incident as the measurement light on the substrate W from the vertical direction. FIG. 7A shows a case in which the direction of the electric field of the measurement light is perpendicular to the trench 92 (Vertical to trench) and a case in which the direction of the electric field of the measurement light is parallel to the trench 92 (Parallel to trench). A direction of the electric field of the measurement light is controlled by, for example, providing an optical element such as a polarizer in the path of the measurement light. In the “Top view” column of “Vertical to trench,” the direction of the electric field of the measurement light is indicated by an arrow in the direction perpendicular to the trench 92. In the “Top view” column of “Parallel to trench,” the direction of the electric field of the measurement light is indicated by an arrow in the direction parallel to the trench 92. In the substrate W in which the trench 92 is formed, when the direction of the electric field of the measurement light is perpendicular to the trench 92 (Vertical to trench), the TO phonons and LO phonons of the film 91 on the surface of the substrate W are observed. In addition, in the substrate W in which the trench 92 is formed, when the direction of the electric field of the measurement light is parallel to the trench 92 (Parallel to trench), the TO phonons of the film 91 on the surface of the substrate W are observed.

FIG. 7B is a view showing an example of an absorbance spectrum in the substrate W in which recesses 90a are formed. FIG. 7B shows an example of results obtained by performing the FT-IR analysis on the substrate W, in which the trench 92 is formed and the film 91 is formed in the trench 92 to obtain an absorbance spectrum. Line L11 indicates an absorbance spectrum in a case of unpolarized light in which the direction of an electric field is not controlled (No). Line L12 indicates an absorbance spectrum in a case in which the direction of the electric field of the measurement light is parallel to the trench 92 (Parallel to trench). Line L13 indicates an absorbance spectrum in a case in which the direction of the electric field of the measurement light is perpendicular to the trench 92 (Vertical to trench). In this way, the shape of the absorbance spectrum changes depending on the direction of the electric field of the measurement light. In the case of the unpolarized light in which the direction of the electric field is not controlled, the direction of the electric field of the measurement light varies. For this reason, TO phonons and LO phonons are observed in the FT-IR analysis using unpolarized measurement light.

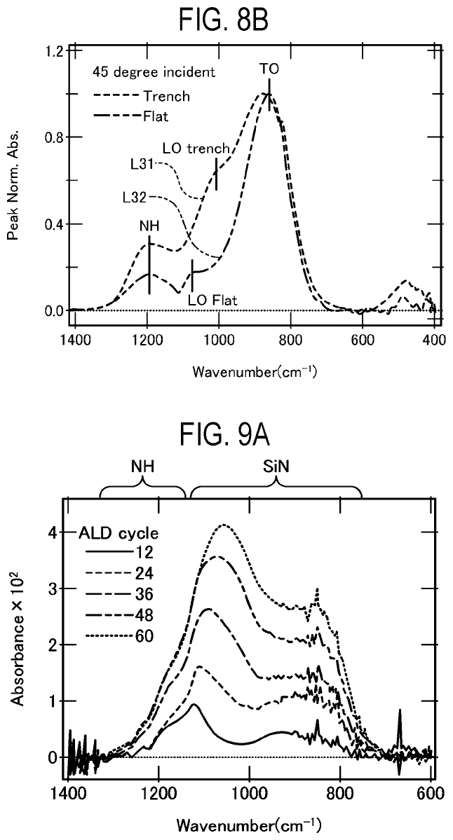

FIGS. 8A and 8B are views showing an example of an absorbance spectrum according to an embodiment. FIG. 8A shows an example of results of the FT-IR analysis using unpolarized measurement light. FIG. 8A shows the example of results of the FT-IR analysis performed with the same type of film formed under the same conditions on the substrate W with the trench 92 formed therein and the flat silicon substrate 95 with the measurement light at an incident angle of 45 degrees C. to obtain an absorbance spectrum. Line L21 indicates an absorbance spectrum of the substrate W (Trench) with the trench 92 formed therein. Line L22 indicates an absorbance spectrum of the flat silicon substrate 95 (Flat). FIG. 8B shows a normalized absorbance spectrum of FIG. 8A. Line L31 indicates the normalized absorbance spectrum of the substrate W (Trench) having the trench 92 shown in line L21, with the peak intensity (absorbance) as a reference. Line L32 indicates the normalized absorbance spectrum of the flat silicon substrate 95 (Flat) shown in line L22, with the peak intensity as a reference.

In this way, the shape of the absorbance spectrum differs between the substrate W and the flat silicon substrate 95. Even if the film 96 formed on the silicon substrate 95 is analyzed by FT-IR, the film thickness of the film 91 formed on the substrate W may not be obtained with high accuracy.

Therefore, in the film thickness measurement method according to this embodiment, the film thickness of the film 91 formed on the substrate W is detected as follows.

First, in the film thickness measurement method according to this embodiment, the relationship information 62a that indicates a relationship between the absorbance spectrum in a range including at least one of the peaks of the LO phonons or the TO phonons of the film 91 present on the surface of the substrate W subjected to the film-forming process, and the film thickness of the film 91 on the substrate W subjected to the film-forming process, is obtained. The relationship information 62a may be generated by actually forming the film 91 on the substrate W and measuring the absorbance spectrum of the formed film 91 and the film thickness of the film 91. The relationship information 62a may also be generated by theoretically calculating the relationship between the absorbance spectrum of the film 91 formed on the substrate W and the film thickness of the film 91.

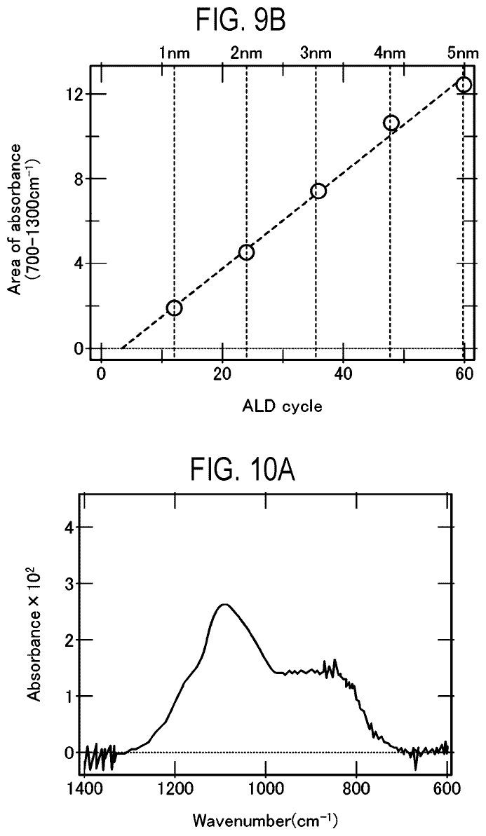

For example, the film forming apparatus 100 forms the films 91 with different film thicknesses on a plurality of substrates W and measures the absorbance spectra of the plurality of substrates W on which the films are formed. In addition, each substrate W is taken out of the film forming apparatus 100, and the film thickness of each of the formed films 91 is measured. FIG. 9A is a view showing an example of an absorbance spectrum according to an embodiment. FIG. 9A shows a case in which the film forming apparatus 100 forms SiN as the film 91 on the substrate W by plasma ALD and measures the absorbance spectrum of the film 91 by the FT-IR analysis using the unpolarized measurement light. FIG. 9A shows a waveform of the measured absorbance spectrum for each cycle number in which the plasma ALD is performed. The film thickness of the formed film 91 increases as the cycle number of the plasma ALD increases. In addition, as shown in FIG. 9A, the waveform of the absorbance spectrum becomes larger overall as the cycle number of the plasma ALD increases. Therefore, there is a correlation between the film thickness of the formed film 91 and the waveform of the absorbance spectrum. In the film thickness measurement method according to this embodiment, the relationship between the absorbance spectrum in the range including at least one of the peaks of the LO phonons or the TO phonons of the film 91 present on the surface of the substrate W and the film thickness of the film 91 on the substrate W subjected to the film-forming process, is obtained. For example, the relationship between a feature amount of the absorbance spectrum in the range including at least one of the peaks of the LO phonons or the TO phonons of the film 91, and the film thickness of the substrate W subjected to the film-forming process, is obtained. The feature amount may be any amount as long as it indicates a feature of the range including at least one of the peaks of the LO phonons or the TO phonons of the absorbance spectrum. For example, the feature amount may be an area of the range including at least one of the peaks of the LO phonons or the TO phonons of the absorbance spectrum, an intensity of the peak in the range, a wave number of the peak in the range, a center-of-gravity wave number of the range, an intensity of the peak of the LO phonons or the TO phonons, and a wave number of the peak of the LO phonons or the TO phonons. The center-of-gravity wave number is a value obtained by dividing an integral value of wave number×absorbance of the range including at least one of the peaks of the LO phonons or the TO phonons of the absorbance spectrum by an integral value of the wave number of the range. The area is a value obtained by integrating the absorbance of the range including at least one of the peaks of the LO phonons or the TO phonons of the absorbance spectrum. Since the area integrates the intensity of the absorbance spectrum, even if the absorbance spectrum includes noise, the influence of the noise may be relatively small.

For example, when SiN is formed as the film 91, the film 91 contains SiN. In addition, the film 91 contains impurities such as NH. The relationship between the absorbance spectrum in the range of the wave number including the peaks of the LO phonons and the TO phonons of SiN and the film thickness of the film 91 is obtained. For example, the peaks of the LO phonons and the TO phonons of SiN appear in a range of the wave number of about 700 to 1,300 cm⁻¹. For example, the relationship between the area of the absorbance spectrum in the range of the wave number of 700 to 1,300 cm⁻¹ for each cycle number shown in FIG. 9A and the film thickness at each cycle number is obtained.

FIG. 9B is a view showing an example of the relationship between the area of the absorbance spectrum and the film thickness according to an embodiment. FIG. 9B shows a graph in which the area of the absorbance spectrum in the range of the wave number of 700 to 1,300 cm⁻¹ is plotted for each cycle number of the plasma ALD by which the film 91 is formed. In addition, in FIG. 9B, the film thickness according to the cycle number of ALD is shown on the horizontal axis on the upper side. As shown in FIG. 9B, there is a proportional relationship between the area and the film thickness (cycle number). The film forming apparatus 100 stores the relationship information 62a indicating such a relationship between the area and the film thickness in the storage 62. The relationship information 62a may be data in a table format that stores the film thickness relative to the area, or may be a relational expression that calculates the film thickness from the area.

The film forming apparatus 100 according to this embodiment forms a film on the substrate W and measures the film thickness of the formed film 91 on an in-line basis. Specifically, the substrate W is transferred to the film forming apparatus 100, and is placed on the stage 2. The film forming apparatus 100 performs the film-forming process on the substrate W. The film forming apparatus 100 measures the absorbance spectrum of the substrate W on which the film-forming process has been performed. Based on the relationship information 62a, the film forming apparatus 100 derives, from the measured absorbance spectrum, the film thickness of the film present on the surface of the substrate W on which the film-forming process has been performed.

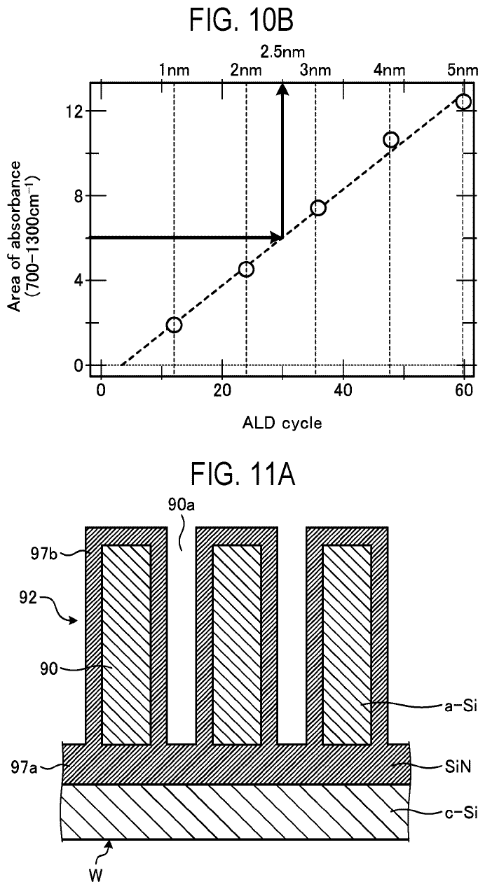

FIGS. 10A and 10B are views for explaining an example of a flow of deriving a film thickness according to an embodiment. For example, FIG. 10A shows an absorbance spectrum measured after forming SiN as the film 91 on the substrate W by the film forming apparatus 100. FIG. 10B shows a graph showing the relationship between the area and the film thickness shown in FIG. 9B. The film forming apparatus 100 calculates the area in the range of the wave number of 700 to 1,300 cm⁻¹ of the absorbance spectrum shown in FIG. 10A. Then, the film forming apparatus 100 derives the film thickness corresponding to the calculated area from the graph of the relationship information 62a shown in FIG. 10B. In FIG. 10B, the film thickness is calculated to be 2.5 nm. In this way, the film forming apparatus 100 may detect the film thickness of the film 91 formed on the substrate W. In addition, since the film forming apparatus 100 may detect the film thickness of the film 91 formed on the substrate W on an in-line basis, it may also perform feedback control on the film-forming process according to the detected film thickness. For example, when the detected film thickness of the film 91 does not satisfy a specified range, the film forming apparatus 100 may control the film thickness of the film 91 to fall within the specified range by performing the film-forming process of the film 91 again. The relationship information 62a may be associated with shape information indicating the shape of the absorbance spectrum for each film thickness of the film 91. The film forming apparatus 100 measures the absorbance spectrum of the film 91 formed on the substrate W. Then, the film forming apparatus 100 may specify shape information, which is close to the shape of the measured absorbance spectrum, from the shape information stored in the relationship information 62a, and derive the film thickness by calculating the film thickness corresponding to the specified shape information.

In the above embodiment, the range of the absorbance spectrum including the peaks of the LO phonons and the TO phonons is set to the range of the wave number of 700 to 1,300 cm⁻¹ when detecting the film thickness of the film 91 formed of SiN. However, the range of the absorbance spectrum is not limited thereto. When detecting the film thickness of the film 91 formed of SiN, the range of the absorbance spectrum may be set to a range of the wave number of 600 to 1,400 cm⁻¹. In addition, when detecting the film thickness of the film 91 formed of SiO, the range of the absorbance spectrum may be a range of the wave number of 900 to 1,300 cm⁻¹, 700 to 900 cm⁻¹, 350 to 600 cm⁻¹, or the like. In addition, when detecting the film thickness of the film 91 formed of SiOCN, the range of the absorbance spectrum may be a range of the wave number of 600 to 1,400 cm⁻¹. In addition, when detecting the film thickness of the film 91 formed of SiCN, the range of the absorbance spectrum may be a range of the wave number of 600 to 1,400 cm⁻¹. In addition, when detecting the film thickness of the film 91 formed of SiN, the range of the absorbance spectrum may be a range of the wave number of 600 to 1,400 cm⁻¹. In addition, when detecting the film thickness of the film 91 formed of HfO, the range of the absorbance spectrum may be a range of the wave number of 600 to 1,400 cm⁻¹.

The film thickness measurement method according to this embodiment may measure the film thickness of a film formed even on the substrate W on which a base film is formed.

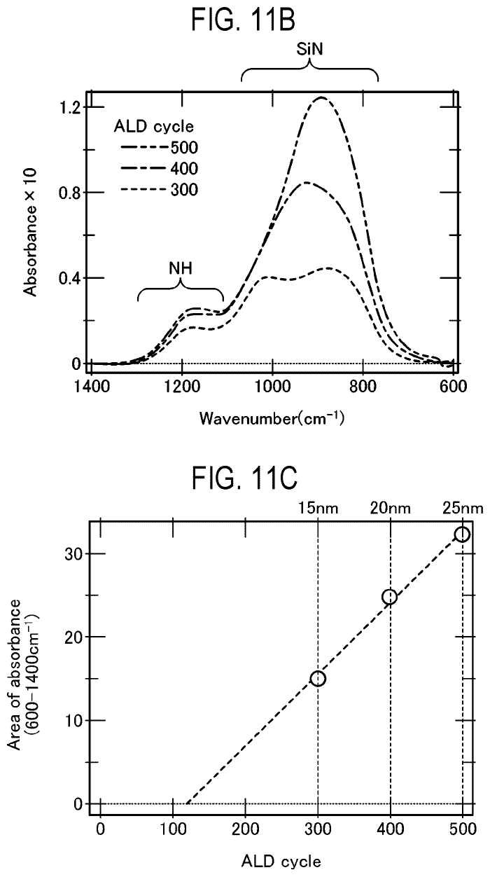

FIG. 11A is a view showing an example of the substrate W on which a film according to an embodiment is formed. The substrate W includes a SiN film 97a formed as a base film on single crystal silicon (c-Si) and a trench 92 formed as a pattern 90 including a plurality of recesses 90a on the SiN film 97a. A SiN film 97b is formed in the trench 92. When measuring the film thickness of the SiN film 97b, the relationship information 62a that indicates the relationship between the absorbance spectrum of the substrate W on which the base film is formed in a range including at least one of the peaks of the LO phonons or the TO phonons of the SiN film 97b and the film thickness of the SiN film 97b, is obtained. For example, as shown in FIG. 11A, the film forming apparatus 100 forms SiN films 97b with different thicknesses on a plurality of substrates W on which base films are formed, and measures the absorbance spectra of the plurality of substrates W on which the SiN films 97b are formed. In addition, each substrate W is taken out of the film forming apparatus 100, and the film thickness of each of the formed SiN films 97b is measured.

FIG. 11B is a view showing an example of an absorbance spectrum according to an embodiment. FIG. 11B shows a case in which the film forming apparatus 100 forms the SiN film 97b on the substrate W on which the SiN film 97a is formed as a base film, as shown in FIG. 11A, and the absorbance spectrum of the SiN film 97b is measured by the FT-IR analysis using unpolarized measurement light. FIG. 11B shows a waveform of the absorbance spectrum measured for each cycle number in which plasma ALD is performed. As shown in FIG. 11B, the waveform of the absorbance spectrum becomes larger overall as the cycle number of plasma ALD increases. For the substrate W on which the base film is formed, the relationship between the absorbance spectrum in the range of the wave number including the peaks of the LO phonons and the TO phonons of SiN and the film thickness of the SiN film 97b is obtained. For example, the relationship between the absorbance spectrum in the range of the wave number of 600 to 1,400 cm⁻¹ and the film thickness of the SiN film 97b is obtained. The range of the wave number may be a range of the wave number of 700 to 1,300 cm⁻¹.

FIG. 11C is a view showing an example of a relationship between an area of the absorbance spectrum and a film thickness according to an embodiment. FIG. 11C shows a graph in which the area of the absorbance spectrum in the range of the wave number of 600 to 1,400 cm⁻¹ is plotted for each cycle number of the plasma ALD by which the SiN film 97b is formed. As shown in FIG. 11C, there is a proportional relationship between the area and the film thickness (cycle number). The relationship information 62a showing such a relationship between the area and the film thickness is stored in the storage 62.

As shown in FIG. 11A, the film forming apparatus 100 performs a film-forming process of the SiN film 97b on the substrate W on which the SiN film 97a is formed as a base film. The film forming apparatus 100 measures the absorbance spectrum of the substrate W on which the film-forming process has been performed. The film forming apparatus 100 derives the film thickness of the SiN film 97b from the measured absorbance spectrum based on the relationship information 62a. In this way, the film forming apparatus 100 may detect the film thickness of the SiN film 97b formed on the substrate W even if the substrate W has a base film formed thereon.

The base film may be a film of a different type from a film to be formed, or may be a plurality of films.

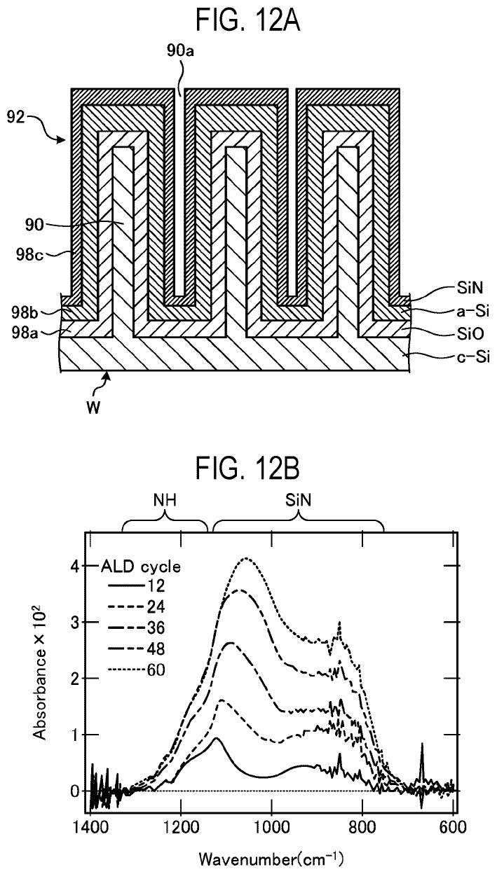

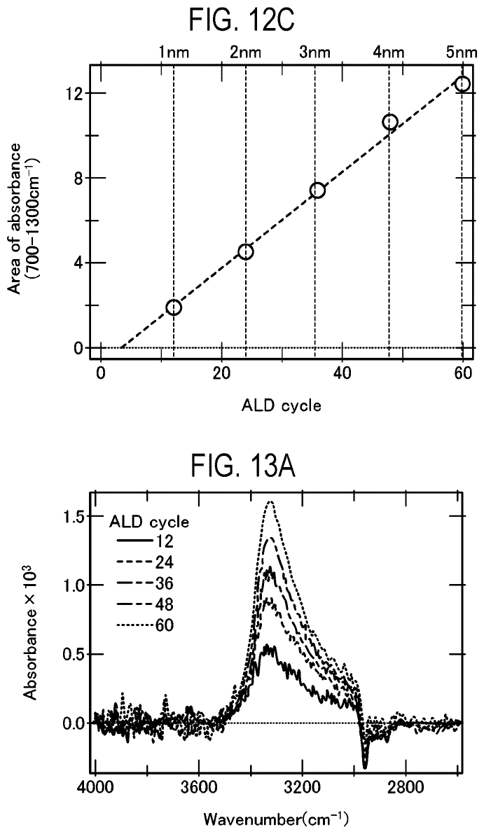

FIG. 12A is a view showing an example of the substrate W on which a film according to the embodiment is formed. The substrate W includes a trench 92 formed as a pattern 90 including a plurality of recesses 90a on single crystal silicon (c-Si). In the trench 92, a SiO film 98a and an amorphous silicon (a-Si) film 98b are formed sequentially as a base film, and a SiN film 98c is formed on the a-Si film 98b. When measuring the film thickness of the SiN film 98c, the relationship information 62a that indicates a relationship between the absorbance spectrum of a range including at least one of the peaks of the LO phonons or the TO phonons of the SiN film 98c for the substrate W on which the base film is formed and the film thickness of the SiN film 98c, is obtained. For example, as shown in FIG. 12A, the film forming apparatus 100 forms SiN films 98c with different thicknesses on a plurality of substrates W on which base films are formed, and measures the absorbance spectra of the plurality of substrates W on which the SiN films 98c are formed. In addition, each substrate W is taken out of the film forming apparatus 100, and the film thickness of each of the formed SiN films 98c is measured.

FIG. 12B is a view showing an example of an absorbance spectrum according to an embodiment. FIG. 12B shows a case in which the film forming apparatus 100 forms the SiN film 98c as a base film shown in FIG. 12A on the substrate W on which the SiO film 98a and the a-Si film 98b are formed, and measures the absorbance spectrum of the SiN film 98c by the FT-IR analysis using unpolarized measurement light. FIG. 12B shows a waveform of the absorbance spectrum measured for each cycle number in which plasma ALD is performed. As shown in FIG. 12B, the waveform of the absorbance spectrum becomes larger overall as the cycle number of the plasma ALD increases. For the substrate W on which the base film is formed, a relationship between the absorbance spectrum in the range of the wave number including the peaks of the LO phonons and the TO phonons of SiN and the film thickness of the SiN film 98c is obtained. For example, a relationship between the absorbance spectrum in the range of the wave number of 700 to 1,300 cm⁻¹ and the film thickness of the SiN film 97b, is obtained.

FIG. 12C is a view showing an example of a relationship between an area of the absorbance spectrum and a film thickness according to an embodiment. FIG. 12C shows a graph in which the area of the absorbance spectrum in the range of the wave number of 700 to 1,300 cm⁻¹ is plotted for each cycle number of the plasma ALD in which the SiN film 98c is formed. As shown in FIG. 12C, there is a proportional relationship between the area and the film thickness (cycle number). The relationship information 62a showing such a relationship between the area and the film thickness is stored in the storage 62.

The film forming apparatus 100 performs a film-forming process of the SiN film 98c on the substrate W on which the SiO film 98a and the a-Si film 98b are formed as a base film, as shown in FIG. 12A. The film forming apparatus 100 measures the absorbance spectrum of the substrate W on which the film-forming process has been performed. The film forming apparatus 100 derives the film thickness of the SiN film 98c from the measured absorbance spectrum based on the relationship information 62a. In this way, the film forming apparatus 100 may detect the film thickness of the SiN film 98c formed on the substrate W even if the substrate W has a base film formed thereon.

In the film-forming process, impurities may be formed together with the intended components. For example, when SiN is formed as the film 91, impurities such as NH are also formed in the film 91 together with SiN. The film thickness measurement method according to this embodiment may measure the film thickness from an absorbance spectrum of the impurities contained in the formed film 91.

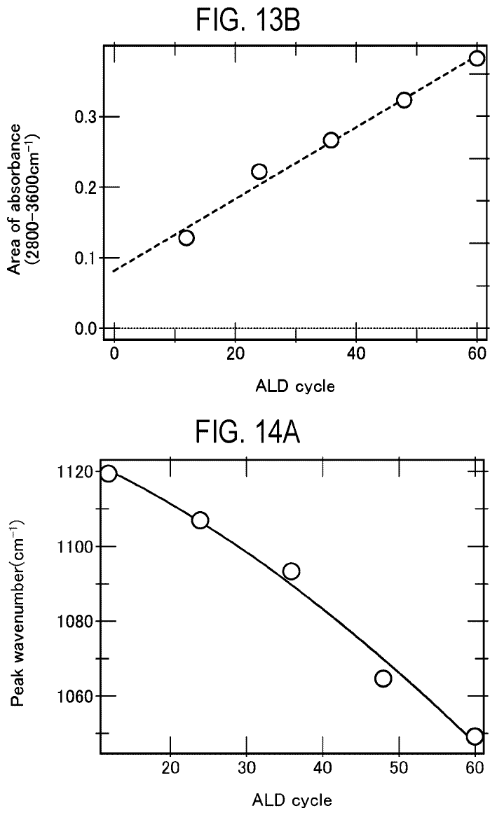

FIG. 13A is a view showing an example of an absorbance spectrum according to an embodiment. FIG. 13A shows a case in which the film forming apparatus 100 forms SiN as the film 91 on the substrate W by plasma ALD and measures the absorbance spectrum of the film 91 by the FT-IR analysis using unpolarized measurement light. In the film 91, impurities such as NH are also formed together with SiN. FIG. 13A shows a waveform of the absorbance spectrum measured for each cycle number in which the plasma ALD is performed. The film thickness of the formed film 91 increases as the cycle number of the plasma ALD increases. In addition, as shown in FIG. 13A, the waveform of the absorbance spectrum increases overall as the cycle number of the plasma ALD increases. Therefore, there is a correlation between the film thickness of the formed film 91 and the waveform of the absorbance spectrum.

A relationship between the absorbance spectrum in the range of the wave number including the peaks of the LO phonons and the TO phonons of the impurities contained in the film 91 and the film thickness of the film 91, is obtained. For example, the peaks of the LO phonons and the TO phonons of NH appear in a range of the wave number of about 2,600 to 3,600 cm⁻¹. For example, the relationship between the area of the absorbance spectrum in the range of the wave number of 2,600 to 3,600 cm⁻¹ for each cycle number shown in FIG. 13A and the film thickness at each cycle number, is obtained.

FIG. 13B is a view showing an example of the relationship between the area of the absorbance spectrum and the film thickness according to an embodiment. FIG. 13B shows a graph in which the area of the absorbance spectrum in the range of the wave number of 2,600 to 3,600 cm⁻¹ is plotted for each cycle number of the plasma ALD by which the film 91 is formed. As shown in FIG. 12B, there is a proportional relationship between the area and the film thickness (cycle number). The relationship information 62a showing such a relationship between the area and the film thickness is stored in the storage 62.

The film forming apparatus 100 forms a film on the substrate W and derives a film thickness of the formed film 91 on an in-line basis. Specifically, the substrate W is transferred to the film forming apparatus 100, and is placed on the stage 2. The film forming apparatus 100 performs a film-forming process on the substrate W. The film forming apparatus 100 measures the absorbance spectrum of the substrate W on which the film-forming process has been performed. Based on the relationship information 62a, the film forming apparatus 100 derives the film thickness of a film present on the surface of the substrate W on which the film-forming process has been performed, from the absorbance spectrum of impurities contained in the formed film among the measured absorbance spectra. In this way, the film forming apparatus 100 may detect the film thickness even from the absorbance spectrum of impurities contained in the formed film 91.

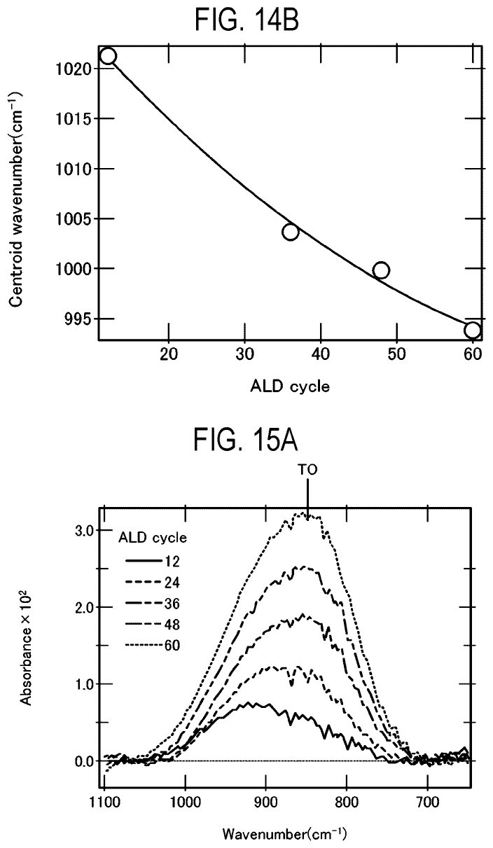

In addition, in the above embodiment, the case in which the area of the absorbance spectrum is used as the feature amount of the absorbance spectrum has been described. However, the present disclosure is not limited thereto. As described above, the feature amount may be any amount as long as it indicates a feature of the absorbance spectrum. For example, the feature amount may be a peak intensity in a range including at least one of the peaks of the LO phonons or the TO phonons of the absorbance spectrum, a wave number of the peak in the range, a center-of-gravity wave number in the range, an intensity of the peak of the LO phonons or the TO phonons, and a wave number of the peak of the LO phonons or the TO phonons. FIGS. 14A and 14B are views showing an example of the relationship between the feature amount of the absorbance spectrum and the film thickness according to an embodiment. FIG. 14A shows a graph in which a peak wave number in the range of the wave number of 700 to 1,300 cm⁻¹ of the absorbance spectrum is plotted for each ALD cycle number, with the feature amount being used as the peak wave number. FIG. 14B shows a graph in which the center-of-gravity wave number in the range of the wave number of 700 to 1,300 cm⁻¹ of the absorbance spectrum is plotted for each ALD cycle number, with the feature amount being used as the center-of-gravity wave number. As shown in FIGS. 14A and 14B, there is a correlation between the peak wave number and the film thickness (cycle number), and between the center-of-gravity wave number and the film thickness (cycle number). Therefore, the film thickness measurement method according to this embodiment may detect the film thickness of the formed film 91 even when the feature amount is used as the peak wave number or the center-of-gravity wave number.

In addition, in the above embodiment, the case in which the film thickness is detected from the absorbance spectrum in the range including the peaks of both the LO phonons and the TO phonons has been described. However, the present disclosure is not limited thereto. In this embodiment, the film thickness may be detected from the absorbance spectrum in a range including the peak of one of the LO phonons and the TO phonons. For example, a peak of the absorbance spectrum for one of the LO phonons and the TO phonons may be obtained, and the film thickness may be detected from the peak of the absorbance spectrum.

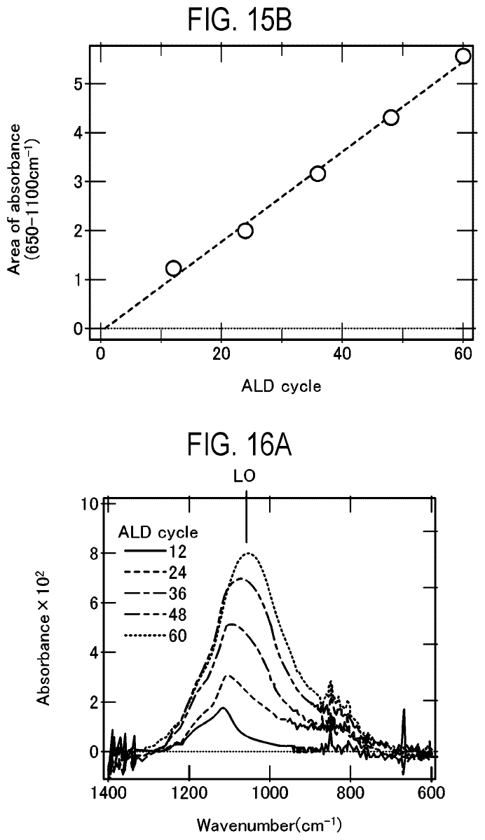

First, a case in which the film thickness is detected from the absorbance spectrum in a range including the peak of the TO phonons will be described. A waveform including the peak of the absorbance spectrum of the TO phonons is obtained by fitting to the absorbance spectrum measured by the FT-IR analysis in which the polarization direction of measurement light is controlled, or by the FT-IR analysis of unpolarized measurement light. For example, as shown in “Parallel to trench” in FIG. 7A, in the substrate W in which the trench 92 is formed, when the direction of the electric field of the measurement light is parallel to the trench 92, the TO phonons of the film 91 on the surface of the substrate W are observed. For example, the film forming apparatus 100 forms films 91 with different film thicknesses on a plurality of substrates W, and measures the absorbance spectra of the plurality substrates W on which the films 91 are formed, by the FT-IR analysis in which the direction of the electric field of the measurement light is parallel to the trench 92. In addition, each substrate W is taken out of the film forming apparatus 100, and the film thickness of the formed film 91 is measured. FIG. 15A is a view showing an example of an absorbance spectrum according to an embodiment. FIG. 15A shows a case in which the film forming apparatus 100 forms SiN as the film 91 on the substrate W by plasma ALD and measures the absorbance spectrum of the film 91 by the FT-IR analysis with the direction of the electric field of the measurement light parallel to the trench 92. In this way, by making the direction of the electric field of the measurement light parallel to the trench 92, a waveform including the peak of the absorbance spectrum of the TO phonons may be measured. The waveform including the peak of the absorbance spectrum of the TO phonons may be obtained by fitting to the absorbance spectrum of the film 91 measured by the FT-IR analysis using unpolarized measurement light. The film thickness of the formed film 91 increases as the cycle number of plasma ALD increases. In addition, as shown in FIG. 15A, the waveform of the absorbance spectrum becomes larger overall as the cycle number of plasma ALD increases. Therefore, there is a correlation between the film thickness of the formed film 91 and the waveform of the absorbance spectrum.

The relationship between the absorbance spectrum in the range of the wave number including the peak of the TO phonons of SiN and the film thickness of the film 91 is obtained. The peak of the TO phonons of SiN appears in a range of the wave number of about 650 to 1,100 cm⁻¹. For example, the relationship between the area of the absorbance spectrum in the range of the wave number of 650 to 1,100 cm⁻¹ for each cycle number shown in FIG. 15A and the film thickness at each cycle number, is obtained.

FIG. 15B is a view showing an example of a relationship between the area of the absorbance spectrum and the film thickness according to an embodiment. FIG. 15B shows a graph in which the area of the absorbance spectrum in the range of the wave number of 650 to 1,100 cm⁻¹ is plotted for each cycle number of the plasma ALD by which the film 91 is formed. As shown in FIG. 15B, there is a proportional relationship between the area and the film thickness (cycle number). Therefore, the film thickness measurement method according to this embodiment may detect the film thickness of the formed film 91 from the absorbance spectrum in the range including the peak of the TO phonons.

Here, as described above, when measuring the absorbance spectrum using the unpolarized measurement light and detecting the film thickness from the absorbance spectrum in the range including the peaks of both the LO phonons and the TO phonons, it is necessary to calculate the area over a wider wave number range of 700 to 1,300 cm⁻¹. On the other hand, when detecting the film thickness from the absorbance spectrum in the range including the peak of the TO phonons, the film thickness may be detected by calculating the area over a narrower wave number range of 650 to 1,100 cm⁻¹.

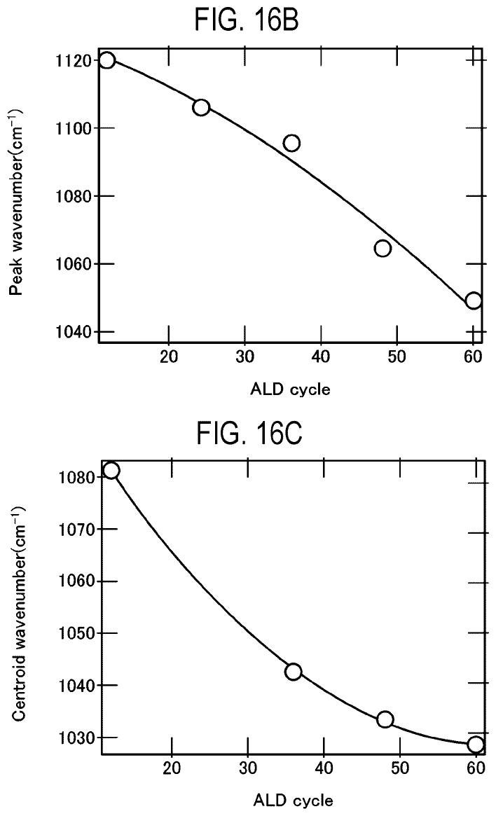

Next, a case in which the film thickness is detected from the absorbance spectrum in the range including the peak of the LO phonons will be described. A waveform including the peak of the absorbance spectrum of the LO phonons is obtained by fitting to the absorbance spectrum measured by the FT-IR analysis of unpolarized measurement light. FIG. 16A is a view showing an example of an absorbance spectrum according to an embodiment. FIG. 16A shows a case in which the fitting is performed on the absorbance spectrum of the film 91 measured by the FT-IR analysis using unpolarized measurement light shown in FIG. 9A to obtain a waveform including the peak of the absorbance spectrum of the LO phonons. The film thickness of the formed film 91 increases as the cycle number of plasma ALD increases. In addition, as shown in FIG. 16A, the waveform of the absorbance spectrum becomes larger overall as the cycle number of plasma ALD increases. Therefore, there is a correlation between the film thickness of the formed film 91 and the waveform of the absorbance spectrum.

The relationship between the absorbance spectrum in the range of the wave number including the peak of the LO phonons of SiN and the film thickness of the film 91 is obtained. The peak of the LO phonons of SiN appears in a range of the wave number of about 700 to 1,300 cm⁻¹. For example, the relationship between the peak wave number in the range of the wave number of 700 to 1,300 cm⁻¹ of the absorbance spectrum for each cycle number shown in FIG. 16A, the center-of-gravity wave number, and the film thickness at each cycle number, is obtained.

FIG. 16B is a view showing an example of a relationship between the peak wave number of the absorbance spectrum and the film thickness according to an embodiment. FIG. 16B shows a graph in which the peak wave number in the range of the wave number of 700 to 1,300 cm⁻¹ of the absorbance spectrum is plotted for each cycle number of the plasma ALD by which the film 91 is formed. FIG. 16C is a view showing an example of a relationship between the center-of-gravity wave number of the absorbance spectrum and the film thickness according to an embodiment. FIG. 16C shows a graph in which the center-of-gravity wave number in the range of the wave number of 700 to 1,300 cm⁻¹ of the absorbance spectrum is plotted for each cycle number of the plasma ALD by which the film 91 is formed. There is a correlation between the peak wave number, the center-of-gravity wave number, and the film thickness. Therefore, the film thickness measurement method according to this embodiment may detect the film thickness of the formed film 91 from the absorbance spectrum in the range including the peak of the LO phonons. In addition, in a case in which the TO phonons or the LO phonons are extracted by polarization control, fitting or the like, the analysis may be performed even with an FT-IR device with a narrow measurable wave number range. In addition, a measurement time may be shortened.

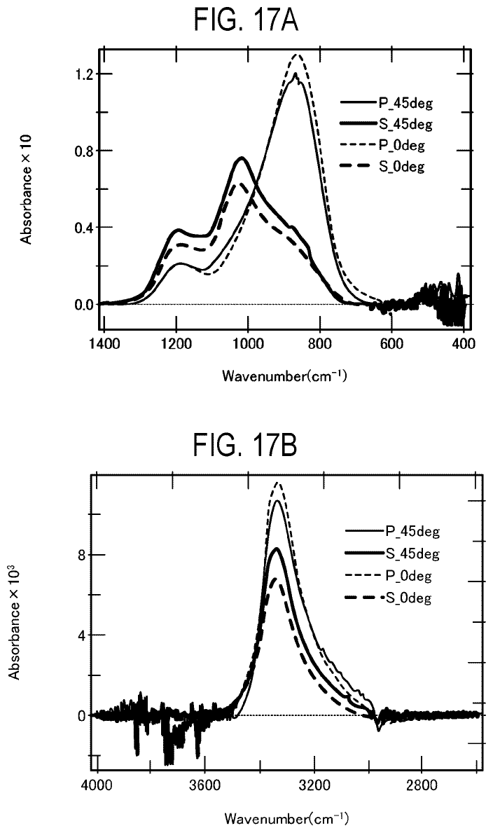

In the film thickness measurement method according to the embodiment, the incident angle of the measurement light on the substrate W during the FT-IR analysis may be any angle. For example, the measurement light may be vertically incident on the substrate W, and the infrared light transmitted through or reflected by the substrate W may be detected to obtain the absorbance spectrum. Alternatively, the measurement light may be obliquely incident on the substrate W, and the infrared light transmitted through or reflected by the substrate W may be detected to obtain the absorbance spectrum. FIGS. 17A and 17B are views showing an example of the absorbance spectrum according to an embodiment. FIGS. 17A and 17B show absorbance spectra when the measurement light is vertically incident on the substrate W at an incident angle of 0 degrees C. (0 deg) and when the measurement light is obliquely incident on the substrate W at an incident angle of 45 degrees C. (45 deg). The measurement light is P-polarized measurement light and S-polarized measurement light, which are incident separately. “P_45 deg” indicates the absorbance spectrum when the P-polarized measurement light is obliquely incident at the incident angle of 45 degrees C. “S_45 deg” indicates the absorbance spectrum when the S-polarized measurement light is obliquely incident at the incident angle of 45 degrees C. “P_0 deg” indicates the absorbance spectrum when the P-polarized measurement light is vertically incident at the incident angle of 0 degrees C. “S_0deg” indicates the absorbance spectrum when the S-polarized measurement light is vertically incident at the incident angle of 0 degrees C. Although there is a difference in peak intensity between the oblique incidence at the incident angle of 45 degrees C. and the vertical incidence at the incident angle of 0 degrees C., the absorbance spectrum has a similar shape. Therefore, the incident angle of the measurement light on the substrate W during the FT-IR analysis may be any angle.

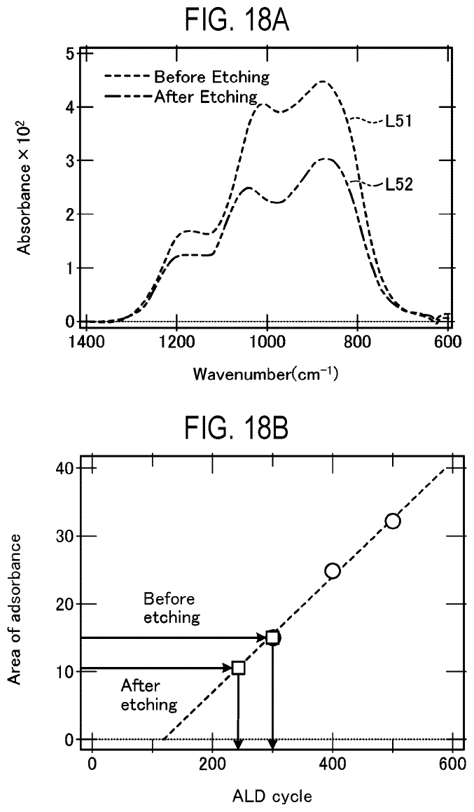

In addition, in the embodiment, the example where the substrate processing is the film-forming process and the film thickness of the film 91 formed on the substrate W is detected has been described, but the present disclosure is not limited thereto. The substrate processing may be any process relating to a semiconductor manufacturing process of manufacturing semiconductor devices, such as an etching process, a modifying process, or a resist coating process. In addition, by detecting the film thickness of the film on the substrate W before and after the substrate processing, a change in the film thickness of the film due to the substrate processing may be detected. For example, by detecting the film thickness of the film 91 on the substrate W before and after the etching process, an amount of etching of the film 91 due to the etching process may be detected. FIG. 18A is a view showing an example of an absorbance spectrum according to an embodiment. FIG. 18A shows line L51 indicating the absorbance spectrum of the substrate W before the etching process and line L52 indicating the absorbance spectrum of the substrate W after the etching process. FIG. 18B is a view for explaining an example of a flow of deriving a change in film thickness according to an embodiment. FIG. 18B shows a graph showing the relationship between the area of the absorbance spectrum and the film thickness. For example, the area in the range of the wave number of 700 to 1,300 cm⁻¹ of the absorbance spectrum before and after the etching process shown in FIG. 18A is obtained. Then, the film thickness, which is the area before and after the etching process, is derived from the graph shown in FIG. 18B. The amount of etching of the film 91 by the etching process may be detected by subtracting the film thickness after the etching process from the film thickness before the etching process.

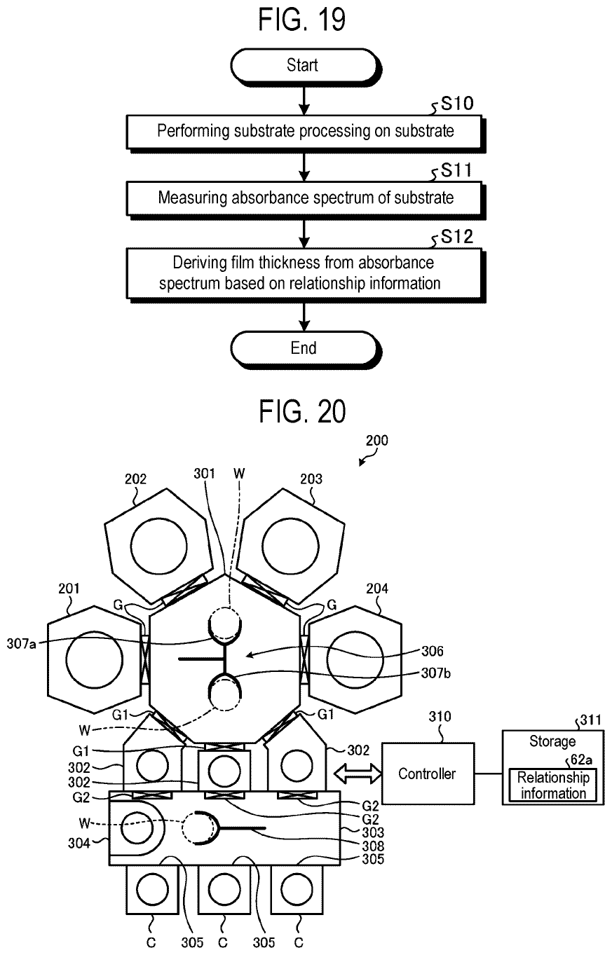

Next, a flow of the film thickness measurement method performed by the film forming apparatus 100 according to the embodiment will be described. FIG. 19 is a flowchart showing an example of the flow of the film thickness measurement method according to an embodiment. In this embodiment, a case in which the film thickness of the substrate W subjected to the film-forming process as the substrate processing is measured will be described as an example.

The substrate W on which the recesses 90a are formed is placed on the stage 2 by a transfer mechanism such as a transfer arm (not shown). The film forming apparatus 100 performs the substrate processing on the substrate W (step S10). For example, the controller 60 controls the exhaust device 73 to reduce the internal pressure of the chamber 1. Then, the controller 60 controls the gas supplier 15 and the radio-frequency power supply 10 to form the film 91 on the surface of the substrate W by plasma ALD.

Subsequently, the film forming apparatus 100 measures the absorbance spectrum of the substrate W subjected to the substrate processing (step S11). The controller 60 controls the irradiator 81 to irradiate the substrate W with the infrared light, and detects the transmitted light that has transmitted through the substrate W or the reflected light that has been reflected by the substrate W using the detector 82. The controller 60 obtains the absorbance spectrum of the substrate W from the data detected by the detector 82.

Subsequently, based on the relationship information 62a, the film forming apparatus 100 derives the film thickness of a film present on the surface of the substrate W on which the substrate processing has been performed, from the measured absorbance spectrum (step S12). For example, the controller 60 obtains the feature amount of the absorbance spectrum in a range including at least one of the peaks of the LO phonons or the TO phonons of the film 91. The controller 60 derives the film thickness corresponding to the obtained feature amount from the relationship information 62a. As a result, the film forming apparatus 100 may detect the film thickness of the film 91 formed on the substrate W.

In this way, the film thickness measurement method according to the embodiment includes a storing operation, a substrate processing operation (step S10), a measuring operation (step S11), and a deriving operation (step S12). In the storing operation, the relationship information 62a indicating the relationship between the absorbance spectrum of the processed substrate W having the recesses 90a formed therein and the film thickness of the film 91 on the substrate W subjected to the substrate processing, the absorbance spectrum being in a range including at least one of the peaks of the LO phonons or the TO phonons of the film 91 present on the surface of the substrate W, is stored in the storage (the storages 62 and 311). In the substrate processing operation, the substrate processing is performed on the substrate W having the recesses 90a formed therein. In the measuring operation, the absorbance spectrum of the processed substrate W is measured. In the deriving operation, the film thickness of the film 91 present on the surface of the substrate W subjected to the substrate processing is derived from the measured absorbance spectrum based on the relationship information 62a. As a result, the film thickness measurement method according to the embodiment may detect the film thickness of the film 91 present on the surface of the substrate W having the recesses 90a formed therein.

In addition, the relationship information 62a stores the relationship between the feature amount of the absorbance spectrum of the substrate W subjected to the substrate processing in the above-mentioned range and the film thickness of the film 91. In the deriving operation, the film thickness is derived from the feature amount of the measured absorbance spectrum in the above-mentioned range based on the relationship information 62a. As a result, the film thickness measurement method according to the embodiment may detect the film thickness of the film 91 subjected to the substrate processing, by obtaining the feature amount of the measured absorbance spectrum in the above-mentioned range.

In addition, the feature amount is any one of the area of the absorbance spectrum in the above-mentioned range, the intensity of the peak in the above-mentioned range, the peak wave number in the above-mentioned range, the center-of-gravity wave number in the above-mentioned range, the intensity of the peak of the LO phonons or the TO phonons, and the peak wave number of the LO phonons or the TO phonons. As a result, the film thickness measurement method according to the embodiment may stably detect the film thickness of the film 91 subjected to the substrate processing.

In addition, the relationship information 62a is generated by actually measuring the absorbance spectrum of the film 91 in the range of the processed substrate W and the film thickness of the film 91 of the substrate W. As a result, the actually-measured relationship between the absorbance spectrum and the film thickness of the film 91 is stored in the relationship information 62a. Thus, the film thickness of the film 91 may be detected with high accuracy from the absorbance spectrum.

In addition, the relationship information 62a is generated by calculating the relationship between the absorbance spectrum of the film 91 of the processed substrate W in the above-mentioned range and the film thickness of the film 91 of the substrate W. As a result, the relationship information 62a may be generated without actually obtaining the relationship between the absorbance spectrum and the film thickness of the film 91 by an experiment or the like.

In addition, the substrate processing is the film-forming process or the etching process. As a result, the film thickness measurement method according to the embodiment may detect the film thickness of the film 91 subjected to the film-forming process or the etching process.

The substrate W includes the trench 92 formed as the recess 90a. The absorbance spectrum is measured as parallel polarization with respect to the trench 92 of the substrate W. As a result, the film thickness measurement method according to the embodiment may detect the film thickness of the film 91 from the absorbance spectrum due to the TO phonons.

In addition, the substrate W includes the trench 92 formed as the recess 90a. The absorbance spectrum is measured as vertical polarization with respect to the trench 92 of the substrate W. As a result, the film thickness measurement method according to the embodiment may detect the film thickness of the film 91 from the absorbance spectrum due to the TO phonons and the LO phonons.

Although the embodiments have been described above, the embodiments disclosed herein should be considered to be illustrative and not restrictive in all respects. Indeed, the above-described embodiments may be embodied in various forms. Further, the above-described embodiments may be omitted, substituted, or modified in various forms without departing from the scope and spirit of the claims.

For example, in the above embodiment, the case in which the irradiator 81 is configured to be movable in the vertical direction and rotatable, and the incident angle of the infrared light incident on the substrate W may be changed has been described, but the present disclosure is not limited thereto. For example, optical elements such as mirrors and lenses may be provided in the optical path of the infrared light emitted from the irradiator 81 or in the optical path of the infrared light incident on the detector 82. The incident angle of the infrared light incident on the substrate W may be changed by the optical elements.

In addition, in the above embodiment, the case in which the infrared light is transmitted or reflected near the center of the substrate W to detect the film thickness of a film near the center of the substrate W has been described, but the present disclosure is not limited thereto. For example, optical elements such as mirrors or lenses that reflect the infrared light may be provided in the chamber 1, the optical elements may irradiate a plurality of locations such as near the center and near the periphery of the substrate W, and the transmitted or reflected light may be detected at each location to detect the film thickness of the substrate W subjected to the substrate processing at each of the plurality of locations of the substrate W.

In addition, in the above embodiment, the case in which the substrate processing apparatus of the present disclosure is a single-chamber type film forming apparatus 100 having one chamber has been described, but the present disclosure is not limited thereto. The substrate processing apparatus of the present disclosure may be a multi-chamber type film forming apparatus having a plurality of chambers.

FIG. 20 is a schematic configuration view showing another example of a film forming apparatus 200 according to an embodiment. As shown in FIG. 20, the film forming apparatus 200 is a multi-chamber type film forming apparatus having four chambers 201 to 204. In the film forming apparatus 200, plasma ALD is performed in each of the four chambers 201 to 204.

The chambers 201 to 204 are connected to four walls of a vacuum transfer chamber 301, which has a heptagonal planar shape, via gate valves G, respectively. An interior of the vacuum transfer chamber 301 is exhausted by a vacuum pump to be maintained at a predetermined level of vacuum. Three load lock chambers 302 are connected to the other three walls of the vacuum transfer chamber 301 via gate valves G1. An atmospheric transfer chamber 303 is provided on the opposite side of the load lock chamber 302 with the vacuum transfer chamber 301 between them. The three load lock chambers 302 are connected to the atmospheric transfer chamber 303 via gate valves G2. The load lock chambers 302 control a pressure between atmospheric pressure and vacuum when transferring the substrate W between the atmospheric transfer chamber 303 and the vacuum transfer chamber 301.

The wall of the atmospheric transfer chamber 303 opposite to the wall of the atmospheric transfer chamber 303 where the load lock chamber 302 is attached is provided with three carrier attachment ports 305 for attaching carriers (FOUPs or the like) C which accommodate substrates W. An alignment chamber 304 for aligning the substrates W is provided on the sidewall of the atmospheric transfer chamber 303. A down-flow of clean air is formed in the atmospheric transfer chamber 303.

A transfer mechanism 306 is provided inside the vacuum transfer chamber 301. The transfer mechanism 306 transfers the substrates W to the chambers 201 to 204 and the load lock chambers 302. The transfer mechanism 306 includes two transfer arms 307a and 307b which are movable independently of each other.

A transfer mechanism 308 is provided inside the atmospheric transfer chamber 303. The transfer mechanism 308 transfers the substrates W to the carriers C, the load lock chambers 302, and the alignment chamber 304.

The film forming apparatus 200 includes a controller 310. An operation of the film forming apparatus 200 is controlled by the controller 310. A storage 311 is connected to the controller 310.

The storage 311 stores programs (software) for implementing various processes executed by the film forming apparatus 200 under the control of the controller 310, as well as data such as process conditions and process parameters. For example, the storage 311 stores the relationship information 62a.

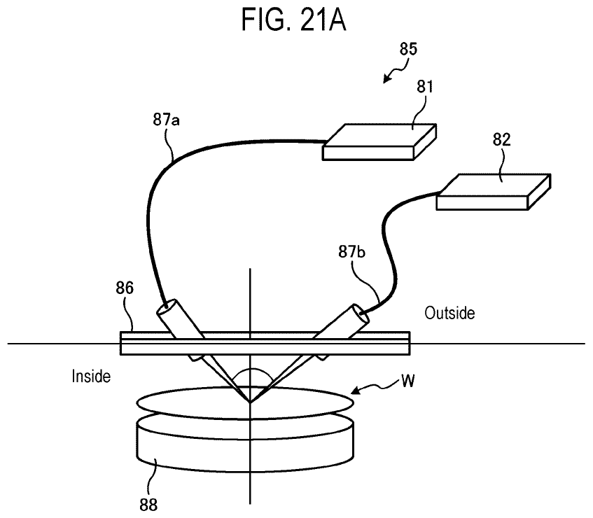

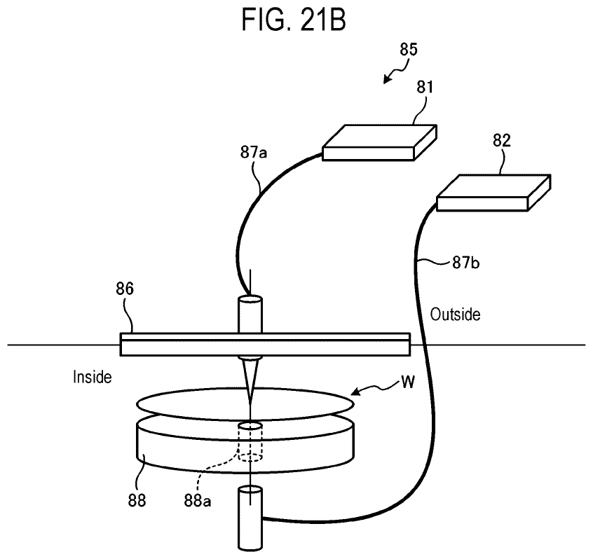

In the film forming apparatus 200 configured in this manner, a measurer 85 for measuring the substrate W by infrared spectroscopy may be provided in a chamber other than the chambers 201 to 204. For example, in the film forming apparatus 200, the measurer 85 for measuring the substrate W by the infrared spectroscopy is provided in any one of the vacuum transfer chamber 301, the load lock chambers 302, the atmospheric transfer chamber 303, and the alignment chamber 304. FIGS. 21A and 21B are views showing examples of a schematic configuration of the measurer 85 according to an embodiment. FIG. 21A shows a case in which the measurer 85 is configured to be capable of performing an infrared spectroscopy analysis by the reflection method. FIG. 21B shows a case in which the measurer 85 is configured to be capable of performing the infrared spectroscopy analysis by the transmission method. The measurer 85 includes an irradiator 81 for irradiating with light and a detector 82 for detecting light. The irradiator 81 and the detector 82 are arranged outside a housing 86 of the vacuum transfer chamber 301, the load lock chambers 302, the atmospheric transfer chamber 303, and the alignment chamber 304. Light guide members 87a and 87b such as optical fibers are connected to the irradiator 81 and the detector 82. End portions of the light guide members 87a and 87b are arranged in the housing 86. Infrared light output from the irradiator 81 is output from the end portion of the light guide member 87a. In FIG. 21A, the end portion of the light guide member 87a is arranged so that the infrared light is incident on the substrate W at a predetermined incident angle (for example, 45 degrees C.). The end portion of the light guide member 87b is arranged so that the infrared light reflected from the substrate W is incident on the end portion of the light guide member 87b. In FIG. 21B, the end portion of the light guide member 87a is arranged so that the infrared light is incident vertically on the substrate W. A stage 88 on which the substrate W is placed includes a through-hole 88a formed at a position where the infrared light is incident. The end portion of the light guide member 87a is arranged above the through-hole 88a. In FIG. 21B, the infrared light incident on the substrate W passes through the through-hole 88a and is incident on the end portion of the light guide member 87b. The infrared light incident on the end portion of the light guide member 87b is detected by the detector 82 via the light guide member 87b. The measurer 85 performs spectroscopic measurement on the substrate W. The controller 310 measures the absorbance spectrum of the substrate W from the infrared light received by the detector 82. Based on the relationship information 62a, the controller 310 derives the film thickness of the film 91 present on the surface of the substrate W subjected to the substrate processing from the measured absorbance spectrum. As a result, the film forming apparatus 200 may also detect the film thickness of the film 91 on the substrate W on an in-line basis.

In addition, as described above, the substrate processing apparatus of the present disclosure has been disclosed as an example of a single chamber or a multi-chamber type substrate processing apparatus including a plurality of chambers, but the present disclosure is not limited thereto. For example, the substrate processing apparatus of the present disclosure may be a batch type substrate processing apparatus capable of processing a plurality of substrates in a batch manner, or may be a carousel type semi-batch type substrate processing apparatus.

According to the present disclosure in some embodiments, it is possible to detect a film thickness of a film present on a surface of a substrate having a recess formed therein.

It should be noted that the embodiments disclosed herein should be considered to be illustrative and not restrictive in all respects. Indeed, the above-described embodiments may be embodied in various forms. Further, the above-described embodiments may be omitted, substituted, or modified in various forms without departing from the scope and spirit of the appended claims.

The following supplementary notes are provided for the above embodiments.

### (Supplementary Note 1)

A method of measuring a film thickness includes: storing, in a storage, relationship information indicating a relationship between an absorbance spectrum of a substrate, which has a recess formed therein and is subjected to substrate processing, and a film thickness of the film in the substrate subjected to the substrate processing, the absorbance spectrum being within a range including a peak of at least one of LO (Longitudinal Optical) phonons or TO (Transverse Optical) phonons of a film present on a surface of the substrate; performing the substrate processing on the substrate having the recess formed therein; measuring the absorbance spectrum of the substrate subjected to the substrate processing; and deriving, based on the relationship information, the film thickness of the film present on the surface of the substrate subjected to the substrate processing, from the measured absorbance spectrum.

### (Supplementary Note 2)

In the method of Supplementary Note 1 above, the relationship information stores a relationship between a feature amount of the absorbance spectrum in the range of the substrate subjected to the substrate processing and the film thickness of the film, and the deriving the film thickness includes deriving the film thickness from the feature amount of the measured absorbance spectrum in the range based on the relationship information.

### (Supplementary Note 3)

In the method of Supplementary Note 2 above, the feature amount is any one of an area of the absorbance spectrum in the range, an intensity of the peak of the range, a wave number of the peak of the range, a center-of-gravity wave number of the range, an intensity of the peak of the LO phonons or the TO phonons, and a wave number of the peak of the LO phonons or the TO phonons.

### (Supplementary Note 4)

In the method of any one of Supplementary Notes 1 to 3 above, the relationship information is generated by actually measuring the absorbance spectrum in the range of the film of the substrate subjected to the substrate processing and the film thickness of the film on the substrate.

### (Supplementary Note 5)

In the method of any one of Supplementary Notes 1 to 3 above, the relationship information is generated by calculating a relationship between the absorbance spectrum in the range of the film on the substrate subjected to the substrate processing and the film thickness of the film on the substrate.

### (Supplementary Note 6)

In the method of any one of Supplementary Notes 1 to 5 above, the substrate processing includes a film-forming process or an etching process.

### (Supplementary Note 7)

In the method of any one of Supplementary Notes 1 to 5 above, the absorbance spectrum is measured by making a measurement light vertically incident on the substrate.

### (Supplementary Note 8)

In the method of any one of Supplementary Notes 1 to 5 above, the absorbance spectrum is measured by making a measurement light obliquely incident on the substrate.

### (Supplementary Note 9)

In the method of any one of Supplementary Notes 1 to 8 above, the substrate has a trench formed as the recess, and the absorbance spectrum is measured as a parallel polarization with respect to the trench in the substrate.

### (Supplementary Note 10)

In the method of any one of Supplementary Notes 1 to 8 above, the substrate has a trench formed as the recess, and the absorbance spectrum is measured as a vertical polarization with respect to the trench in the substrate.

### (Supplementary Note 11)

A substrate processing apparatus includes: a storage storing relationship information indicating a relationship between an absorbance spectrum of a substrate, which has a recess formed therein and is subjected to substrate processing, and a film thickness of the film in the substrate subjected to the substrate processing, the absorbance spectrum being within a range including a peak of at least one of LO (Longitudinal Optical) phonons or TO (Transverse Optical) phonons of a film present on a surface of the substrate; a substrate processor configured to perform the substrate processing on the substrate having the recess formed therein; a measurer configured to measure the absorbance spectrum of the substrate subjected to the substrate processing by the substrate processor; and a deriver configured to derive, based on the relationship information, the film thickness of the film present on the surface of the substrate subjected to the substrate processing, from the absorbance spectrum measured by the measurer.

What is claimed is:

1. A method of measuring a film thickness, comprising:
storing, in a storage, relationship information indicating a relationship between an absorbance spectrum of a substrate, which has a recess formed therein and is subjected to substrate processing, and a film thickness of a film in the substrate subjected to the substrate processing, the absorbance spectrum being within a range including a peak of at least one of LO (Longitudinal Optical) phonons or TO (Transverse Optical) phonons of the film present on a surface of the substrate;
performing the substrate processing on the substrate having the recess formed therein;
measuring the absorbance spectrum of the substrate subjected to the substrate processing; and
deriving, based on the relationship information, the film thickness of the film present on the surface of the substrate subjected to the substrate processing, from the measured absorbance spectrum.

2. The method of claim 1, wherein the relationship information stores a relationship between a feature amount of the absorbance spectrum in the range of the substrate subjected to the substrate processing and the film thickness of the film, and
wherein the deriving the film thickness includes deriving the film thickness from the feature amount of the measured absorbance spectrum in the range based on the relationship information.

3. The method of claim 2, wherein the feature amount is any one of an area of the absorbance spectrum in the range, an intensity of the peak of the range, a wave number of the peak of the range, a center-of-gravity wave number of the range, an intensity of the peak of the LO phonons or the TO phonons, and a wave number of the peak of the LO phonons or the TO phonons.

4. The method of claim 1, wherein the relationship information is generated by actually measuring the absorbance spectrum in the range of the film of the substrate subjected to the substrate processing and the film thickness of the film on the substrate.

5. The method of claim 1, wherein the relationship information is generated by calculating a relationship between the absorbance spectrum in the range of the film on the substrate subjected to the substrate processing and the film thickness of the film on the substrate.

6. The method of claim 1, wherein the substrate processing includes a film-forming process or an etching process.

7. The method of claim 1, wherein the absorbance spectrum is measured by making a measurement light vertically incident on the substrate.

8. The method of claim 1, wherein the absorbance spectrum is measured by making a measurement light obliquely incident on the substrate.

9. The method of claim 1, wherein the substrate has a trench formed as the recess, and
wherein the absorbance spectrum is measured as a parallel polarization with respect to the trench in the substrate.

10. The method of claim 1, wherein the substrate has a trench formed as the recess, and
wherein the absorbance spectrum is measured as a vertical polarization with respect to the trench in the substrate.

11. A substrate processing apparatus comprising:
a storage storing relationship information indicating a relationship between an absorbance spectrum of a substrate, which has a recess formed therein and is subjected to substrate processing, and a film thickness of a film in the substrate subjected to the substrate processing, the absorbance spectrum being within a range including a peak of at least one of LO (Longitudinal Optical) phonons or TO (Transverse Optical) phonons of the film present on a surface of the substrate;
a substrate processor configured to perform the substrate processing on the substrate having the recess formed therein;
a measurer configured to measure the absorbance spectrum of the substrate subjected to the substrate processing by the substrate processor; and
a deriver configured to derive, based on the relationship information, the film thickness of the film present on the surface of the substrate subjected to the substrate processing, from the absorbance spectrum measured by the measurer.
